(19) United States
(12) Patent Application Publication
(10) Pub. No.: US 2025/0359002 A1
(43) Pub. Date: Nov. 20, 2025

(54) BIT LINE STRUCTURE FOR MEMORY DEVICES

(71) Applicant: Taiwan Semiconductor Manufacturing Company, Ltd., Hsin-Chu (TW)

(72) Inventors: Feng-Ming Chang, Hsinchu County (TW); Jui-Lin Chen, Taipei City (TW); Ping-Wei Wang, Hsin-Chu (TW); Jui-Wen Chang, Hsinchu (TW); Lien-Jung Hung, Taipei (TW)

(21) Appl. No.: 19/283,568

(22) Filed: Jul. 29, 2025

Related U.S. Application Data
(63) Continuation of application No. 18/428,623, filed on Jan. 31, 2024.
(60) Provisional application No. 63/588,859, filed on Oct. 9, 2023.

(51) Int. Cl. H10B 10/00

(52) U.S. Cl. CPC H10B 10/125; H10B 10/18

(57) ABSTRACT

A semiconductor structure according to the present disclosure includes a first memory array in a first cache and a second memory array in a second cache. The first memory array includes a plurality of first memory cells arranged in M1 rows and N1 columns. The second memory array includes a plurality of second memory cells arranged in M2 rows and N2 columns. The semiconductor structure also includes a first bit line coupled to a number of N1 first memory cells in one of the M1 rows, and a second bit line coupled to a number of N2 second memory cells in one of the M2 rows. N1 is smaller than N2, and a width of the first bit line is smaller than a width of the second bit line.

### PRIORITY DATA

This is a continuation application of U.S. patent application Ser. No. 18/428,623, filed Jan. 31, 2024, which claims benefit of U.S. Provisional Patent Application Ser. No. 63/588,859, filed Oct. 9, 2023, each of which is incorporated herein by reference in its entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Such scaling down in integrated circuit technology has not only complicated the manufacturing processes but also raised specific challenges in the design and functionality of memory arrays within memory devices. For example, operations of memory arrays in different cache levels (e.g., level-1 cache and level-2 cache) raise a need for tailored structural designs for respective signal lines (e.g., bit lines). The traditional approach of employing bit lines with one uniform width across different cache levels is increasingly inadequate, as it does not optimally address the varying performance demands of these caches. Uniform bit line structures across these caches can lead to suboptimal performance, where the specific needs of each cache type (e.g., low parasitic capacitance in level-1 cache and low voltage drop in level-2 cache) are not fully met. This discrepancy highlights the need for a differentiated approach in bit line architecture to enhance the overall efficiency and performance of memory devices, particularly in the context of advanced semiconductor technologies.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a block diagram of an integrated circuit (IC) having a memory circuit, according to various aspects of the present disclosure.

FIG. 2 is a block diagram of a memory macro having a memory array, according to various aspects of the present disclosure.

FIG. 3 is a circuit schematic of a static random-access memory (SRAM) cell, according to various aspects of the present disclosure.

FIG. 4 illustrates a cross-sectional view of various layers of a memory device, according to various aspects of the present disclosure.

FIGS. 5 and 6 illustrate a layout including device layer and metal layer, respectively, of the SRAM cell as in FIG. 3, according to various aspects of the present disclosure.

FIGS. 7 and 8 illustrate a layout including device layer and metal layer, respectively, of a portion of the memory macro as in FIG. 2, according to various aspects of the present disclosure.

FIG. 9 illustrates a layout including device layer and metal layer of a portion of a memory circuit that includes at least two different memory arrays, according to various aspects of the present disclosure.

FIG. 10 illustrates options of design parameters implemented in a memory circuit, according to various aspects of the present disclosure.

FIG. 11 illustrates fragmentary cross-sectional views along cross sections A-A, B-B, A′-A′, and B′-B′ in FIG. 9, according to various aspects of the present disclosure.

FIG. 12 is a block diagram of an IC manufacturing flow, according to various aspects of the present disclosure.

FIG. 13 is a flow chart of a method of adjusting bit line widths in an IC layout, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

Static Random Access Memory (SRAM) is a semiconductor memory that retains data statically as long as it is powered. Unlike dynamic RAM (DRAM), SRAM is faster and more reliable, eliminating the need for constant refreshing. SRAM is extensively utilized in various applications, including computer memory. A computer memory may include different cache levels, such as level-1 caches and level-2 caches. Each cache level may have different structural design needs to achieve optimal performance. For instance, a level-1 cache, being the fastest cache, may prefer a structural design for its signal lines that minimizes latency and maximizes data transfer rates with reduced parasitic capacitance. In contrast, a level-2 cache, acting as a secondary buffer and situated further from the CPU, may prefer a structural design for its signal lines that lowers resistance to afford a larger voltage headroom. In the context of bit line structures, one uniform bit line width across different cache levels might result in suboptimal performance, as it does not meet the unique requirements of each cache type.

The present disclosure introduces a bit line structure providing different bit line widths for SRAM arrays across different cache levels. In one embodiment, a memory device may feature two or more bit line widths for SRAM arrays at different cache levels, enhancing performance to suit diverse needs. Another embodiment allows for different bit line widths within SRAM arrays of the same cache level but with different sizes, further optimizing the performance of the memory device. Additionally, pairing different bit line widths with various SRAM cell designs, such as high-current and high-density cell designs, is proposed to further optimize the performance of memory devices.

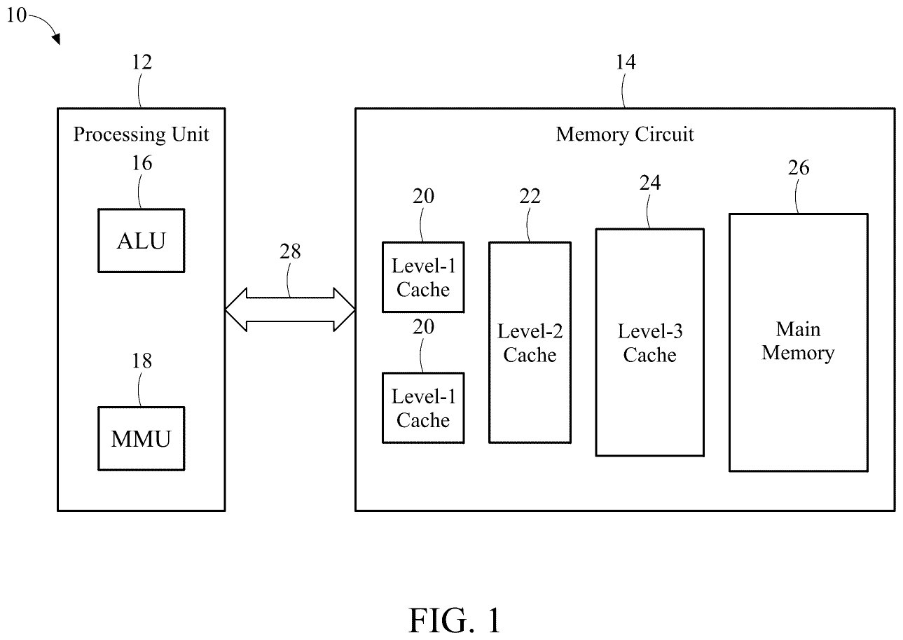

FIG. 1 shows a simplified block diagram of an IC 10, in accordance with some embodiments. The IC 10 includes a processing unit 12, which as illustrated includes an arithmetic logic unit (ALU) 16 and a memory management unit (MMU) 18, and a memory circuit 14 integrated in the IC 10. The processing unit 12 may include various components such as one or more flip-flops, one or more scan chains, one or more registers, etc., which are omitted from FIG. 1 for case of illustration.

The memory circuit 14 includes memory cells (e.g., SRAM cells and/or DRAM cells) organized into one or more level-1 caches 20, one or more level-2 caches 22, one or more level-3 caches 24, and a main memory 26. Optionally, the memory circuit 14 may further includes one or more level-n caches (n>3). Any suitable type of SRAM cells and/or DRAM cells may be employed. For example, the level-1 cache 20, the level-2 cache 22, and the level-3 cache 24 May be implemented by the SRAM cells, while the main memory 26 may be implemented by the DRAM cells. The processing unit 12 and the memory circuit 14 are communicatively coupled together by an internal bus system 28 in the IC 10.

Generally, the level-1 caches 20 are the fastest cache memory and used to store data that is accessed by the processing unit 12 recently. Furthermore, the level-1 caches 20 are the first caches to be accessed and processed when the processing unit 12 performs a computer instruction. The level-2 cache 22 may not be as fast as the level-1 caches 20, but the capacity can be increased. The level-3 cache 24 works together with the level-1 and level-2 caches to improve computer performance by preventing bottlenecks due to the fetch-execute cycle taking too long. Furthermore, memory performance of the level-3 cache 24 is slower compared to the level-2 cache 22. For example, the level-1 caches 20 may typically have a faster response time than the level-2 cache 22, and the level-2 cache 22 may typically have a faster response time than the level-3 cache 24. Regarding memory capacity, the level-1 caches 20 is smaller compared to the level-2 cache 22, and the level-2 cache 22 is smaller compared to the level-3 cache 24. For example, one level-1 cache 20 may include 64K memory bits, one level-2 cache 22 may include 128K memory bits, and one level-3 cache 24 may include 512K or even more memory bits.

The one or more processing units 12, in operation, generate one or more signals to control operation of the IC 10. Such functionality may be provided by, for example, the processing unit 12 executing instructions retrieved from the memory circuit 14. The MMU 18 of the processing unit 12, in operation, may control storage and retrieval of data and instructions from the level-1 cache 20, the level-2 cache 22, the level-3 cache 24, and the main memory 26 of the memory circuit 14 via the internal bus system 28, and/or from one or more memories external to the IC 10 via one or more interfaces (not shown). The MMU 18 may include a plurality of addressing circuits, which may facilitate simultaneous use of the level-1 cache 20, the level-2 cache 22, the level-3 cache 24, and the main memory 26.

Memory management routines (e.g., cache control routines) may be employed to control the transfer of data and instructions between the level-1 cache 20, the level-2 cache 22, the level-3 cache 24, and the main memory 26. Embodiments of the IC 10 may have fewer components than illustrated (e.g., level-3 cache 24 may be optional), may have more components than illustrated, may combine or separate illustrated components, and may re-arrange the illustrated components. For example, the MMU 18 may be split into multiple MMUs 18 (e.g., a first MMU 18 for controlling the level-1 caches 20, a second MMU 18 for controlling the level-2 cache 22 and the level-3 cache 24, and a third MMU 18 for controlling the main memory 26). In another example, the MMU 18 may be part of the memory circuit 14 instead of the processing unit 12.

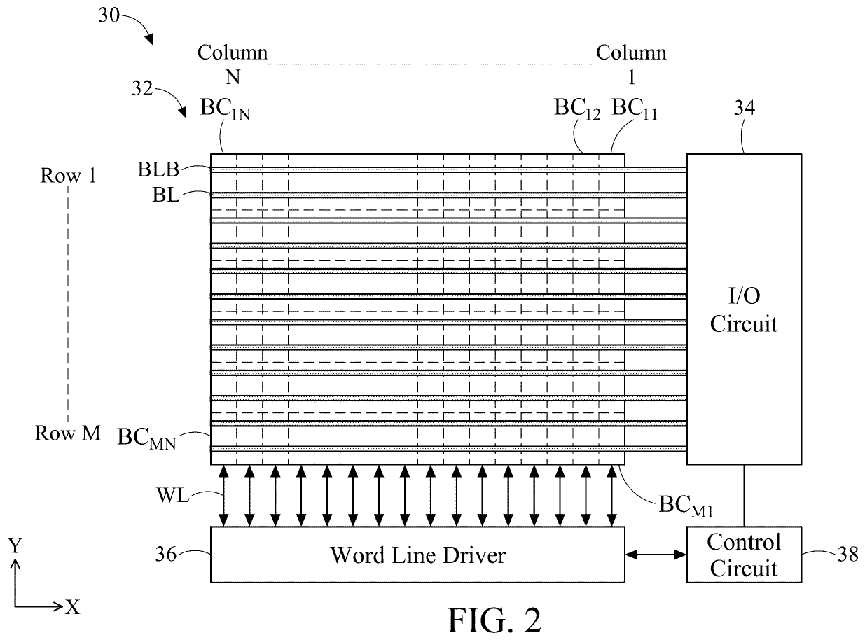

FIG. 2 shows a memory macro 30, which can be implemented in the memory circuit 14 in FIG. 1. For example, the memory macro 30 may be a portion of the level-1 cache 20, the level-2 cache 22, the level-3 cache 24, or the main memory 25 in the memory circuit 14. In the illustrated embodiment, the memory macro 30 is an SRAM macro, such as a single-port SRAM macro, a dual-port SRAM macro, or other types of SRAM macro. However, the present disclosure contemplates embodiments, where memory macro 30 is another type of memory, such as a dynamic random access memory (DRAM), a non-volatile random access memory (NVRAM), a flash memory, or other suitable memory. FIG. 2 has been simplified for the sake of clarity to better understand the inventive concepts of the present disclosure. Additional features can be added in the memory macro 30, and some of the features described below can be replaced, modified, or eliminated in other embodiments of the memory macro 30.

The memory macro 30 includes a memory array 32, an input/output (I/O) circuit 34, a word line driver 36, and a control circuit 38. The memory array 32 includes memory cells arranged in rows and columns. In the illustrated embodiment, the memory cells are arranged from Row 1 to Row M each extending along a first direction (here, in the X direction) and in Column 1 to Column N each extending along a second direction (here, in the Y direction), where M and N are positive integers. For simplicity of illustration, only a few rows and a few columns and the corresponding memory cells are shown in FIG. 2. Each memory cell stores one bit of data. Accordingly, a memory cell is also referred to as a bit cell or denoted as BCₘₙ according to its location in the memory array 32, where m representing the row and n representing the column. For example, BC₁₁ represents the memory cell located in the first row (Row 1) and the first column (Column 1), which is the memory cell closest to the I/O circuit 34 in the first row (Row 1); BC₁₂ represents the memory cell located in the first row (Row 1) and the second column (Column 2), which is the memory cell second closest to the I/O circuit 34 in the first row (Row 1); BC_{IN} represents the memory cell located in the first row (Row 1) and the last column (Column N), which is the memory cell farthest away from the I/O circuit 34 in the first row (Row 1); and BC_{MN} represents the memory cell located in the last row (Row M) and the last column (Column N), which is the memory cell farthest away from the I/O circuit 34 in the last row (Row M). A memory cell BCₘₙ may be referred to as a BC for simplicity.

Rows 1 to M each include a bit line pair extending along the X direction, such as a bit line (BL) and a bit line bar (BLB) (also referred to as a complementary bit line), that facilitate reading data from and/or writing data to respective memory cells BC in true form and complementary form on a row-by-row basis. Columns 1 to M each includes a word line (WL) that facilitates access to respective memory cells BC on a column-by-column basis. Each memory cell BC is electrically connected to a respective BL, a respective BLB, and a respective WL.

The I/O circuit 34 is coupled to the memory array 32 through the bit line pairs BL and BLB. The I/O circuit 34 is configured to select one of the rows in the memory array 32, and to provide bit line signal on one of the bit line pairs that is arranged on the selected row, in some embodiments. The bit line signal is transmitted through the selected bit line pair BL and BLB to the corresponding memory cells BC, for writing the bit data into, or reading the bit data from, the corresponding memory cells BC.

The word line driver 36 is coupled to the memory array 32 through the word lines WL. The word line driver 36 is configured to select one of the columns in the memory array 32, and to provide word line signal on one of the word lines WL that is arranged on the selected column, in some embodiments. The word line signal is transmitted through the selected word line WL to the corresponding memory cells BC, for writing the bit data into, or reading the bit data from, the corresponding memory cells BC.

The control circuit 38 is coupled to and disposed next to both of the I/O circuit 34 and the word line driver 36. The control circuit 38 configures the I/O circuit 34 and the word line driver 36 to generate one or more signals to select at least one WL and at least one bit line pair (here, BL and BLB) to access at least one of memory cells BC for read operations and/or write operations. The control circuit 38 includes any circuitry suitable to facilitate read/write operations from/to memory cells BC, including but not limited to, a column decoder circuit, a row decoder circuit, a column selection circuit, a row selection circuit, a read/write circuit (for example, configured to read data from and/or write data to memory cells BC corresponding to a selected bit line pair (in other words, a selected column)), other suitable circuit, or combinations thereof. In some embodiments, the control circuit 38 is implemented by a processor. In some other embodiments, the control circuit 130 is integrated with a processor. The processor is implemented by a central processing unit (CPU), a multi-processor, a distributed processing system, an application specific integrated circuit (ASIC), and/or a suitable processing unit.

In a write or read operation, at least one bit line pair and at least one word line WL are respectively selected by the I/O circuit 34 and the word line driver 36. When one word line WL on one corresponding column is selected, the bit line signal is transmitted from the I/O circuit 34 to one corresponding memory cell BC, or the bit line signal is transmitted from the memory cell BC to the I/O circuit 34. For a smaller memory array 32, such as a memory array in a level-1 cache, the transmitting path along the signal lines in the bit line pair (here, BL and BLB extending through Columns 1 to N) gets shorter; in a comparison, for a larger memory array 32, such as memory array in a level-2 cache, the transmitting path along the signal lines in the bit line pair (here, BL and BLB extending through Columns 1 to N) gets longer. Shorter transmitting path due to a smaller array can lead to faster access time and lower power consumption, as the reduced capacitance and resistance facilitate quicker signal transmission and reduced dynamic power dissipation. Conversely, longer transmitting path in a larger array can increase resistance and capacitance, potentially slowing down access time and elevating power consumption. Accordingly, dimensions of the signal lines in the bit line pair directly influence performance optimization in different levels of cache memories in computing systems.

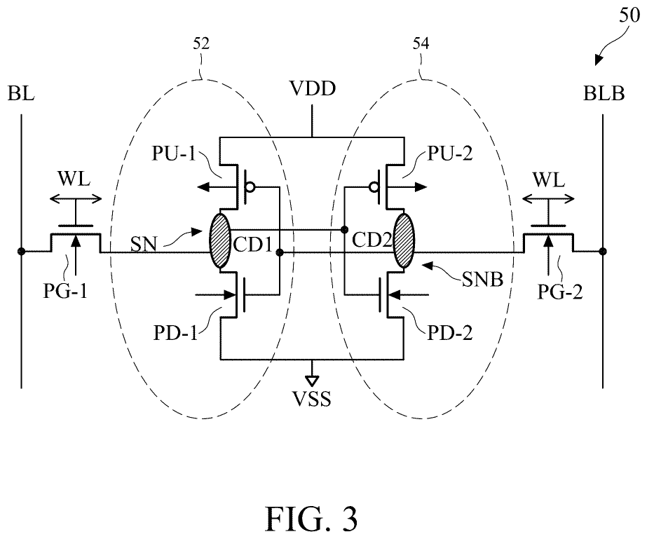

FIG. 3 is a circuit diagram of an exemplary SRAM cell 50, which can be implemented as a memory cell BC in FIG. 2 and further implemented in one or more caches and memories in FIG. 1. In the illustrated embodiment, the SRAM cell 50 is a single-port (SP) six-transistor (6T) SRAM cell. In various embodiments, the SRAM cell 50 may be other types of memory cells, such as dual-port memory cell or a memory cell having more than six transistors. FIG. 3 has been simplified for the sake of clarity to better understand the inventive concepts of the present disclosure. Additional features can be added in single-port SRAM cell 50, and some of the features described below can be replaced, modified, or eliminated in other embodiments of single-port SRAM cell 50.

The exemplary SRAM cell 50 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 50, which includes a cross-coupled pair of inverters, an inverter 52 and an inverter 54. The inverter 52 includes the pull-up transistor PU-1 and the pull-down transistor PD-1, and the inverter 54 includes the pull-up transistor PU-2 and the pull-down transistor PD-2. In some implementations, the pull-up transistors PU-1, PU-2 are configured as p-type FinFET transistors or p-type GAA transistors, and the pull-down transistors PD-1, PD-2 are configured as n-type FinFET transistors or n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

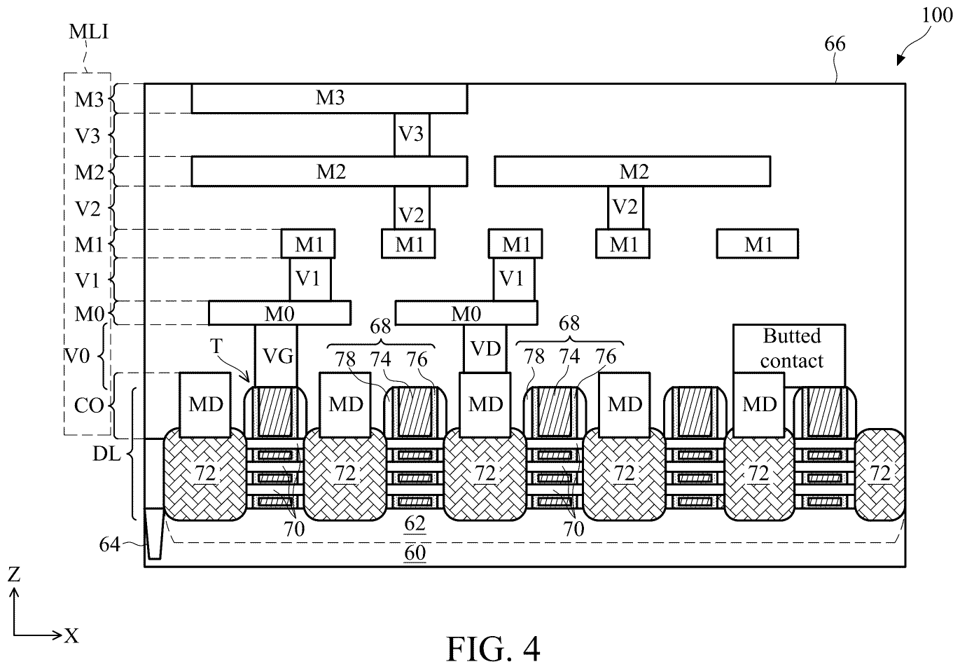

FIG. 4 is a fragmentary diagrammatic cross-sectional view of a semiconductor device 100 including various layers (levels) that can be fabricated over a semiconductor substrate (or wafer) 60 to form a portion of a memory, such as the memory macro 30 of FIG. 2, and/or a portion of an SRAM cell, such as the SRAM cell 50 of FIG. 3, according to various aspects of the present disclosure. In FIG. 4, the various layers include a device layer DL and a multilayer interconnect MLI disposed over the device layer DL. Device layer DL includes devices (e.g., transistors, resistors, capacitors, and/or inductors) and/or device components (e.g., doped wells, gate structures, and/or source/drain features). In some embodiments, device layer DL includes substrate 60, doped regions 62 disposed in substrate 60 (e.g., n-wells and/or p-wells), isolation features 64, and transistors T. In the depicted embodiment, transistors T include suspended channel layers 70 and gate structures 68 disposed between source/drains 72, where gate structures 68 wrap and/or surround suspended channel layers 70. Each gate structure 68 has a metal gate stack formed from a gate electrode 74 disposed over a gate dielectric 76 and gate spacers 78 disposed along sidewalls of the metal gate stack. Multilayer interconnect MLI electrically couples various devices and/or components of device layer DL, such that the various devices and/or components can operate as specified by design requirements for the memory.

In the depicted embodiment, multilayer interconnect MLI includes a contact layer (CO level), a via zero layer (V0 level), a metal zero (M0) level, a via one layer (V1 level), a metal one layer (M1 level), a via two layer (V2 level), a metal two layer (M2 level), a via three layer (V3 level), and a metal three layer (M3 level). The present disclosure contemplates multilayer interconnect MLI having more or less layers and/or levels, for example, a total number of 2 to 10 metal layers (levels) of the multilayer interconnect MLI. Each level of multilayer interconnect MLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of multilayer interconnect MLI, such as M0 level, are formed simultaneously. In some embodiments, conductive features at a same level of multilayer interconnect MLI have top surfaces that are substantially planar with one another and/or bottom surfaces that are substantially planar with one another. C0 level includes source/drain contacts (MD) disposed in a dielectric layer 66; V0 level includes gate vias VG, source/drain contact vias VD, and butted contacts disposed in the dielectric layer 66; M0 level includes M0 metal lines disposed in dielectric layer 66, where gate vias VG connect gate structures to M0 metal lines, source/drain vias V0 connect source/drains to M0 metal lines, and butted contacts connect gate structures and source/drains together and to M0 metal lines; V1 level includes V1 vias disposed in the dielectric layer 66, where V1 vias connect M0 metal lines to M1 metal lines; M1 level includes M1 metal lines disposed in the dielectric layer 66; V2 level includes V2 vias disposed in the dielectric layer 66, where V2 vias connect M1 lines to M2 lines; M2 level includes M2 metal lines disposed in the dielectric layer 66; V3 level includes V3 vias disposed in the dielectric layer 66, where V3 vias connect M2 lines to M3 lines.

An exemplary manufacturing flow of forming the device layer DL and the multilayer interconnect MLI of the semiconductor device 100, according to various aspects of the present disclosure, may include forming active regions on a substrate, forming isolation structures (e.g., shallow-trench isolation (STI)) between adjacent active regions, forming dummy gates over the active regions and gate spacers on sidewalls of the dummy gates, recessing the active regions to form source/drain recesses, forming inner spacers and source/drain features in the source/drain recesses, depositing interlayer dielectric (ILD) layer over the source/drain features and the dummy gate structure, performing a planarization process (e.g., a chemical mechanical planarization (CMP) process) to expose the dummy gate structures, replacing the dummy gate structures with metal gate structures, and forming contacts, vias, and metal layers in the multilayer interconnect MLI.

FIG. 4 has been simplified for the sake of clarity to better understand the inventive concepts of the present disclosure. Additional features can be added in the various layers of the memory, and some of the features described can be replaced, modified, or eliminated in other embodiments of the memory. FIG. 4 is merely an example and may not reflect an actual cross-sectional view of the memory macro 30 and/or the SRAM cells 50 that is discussed in further detail below.

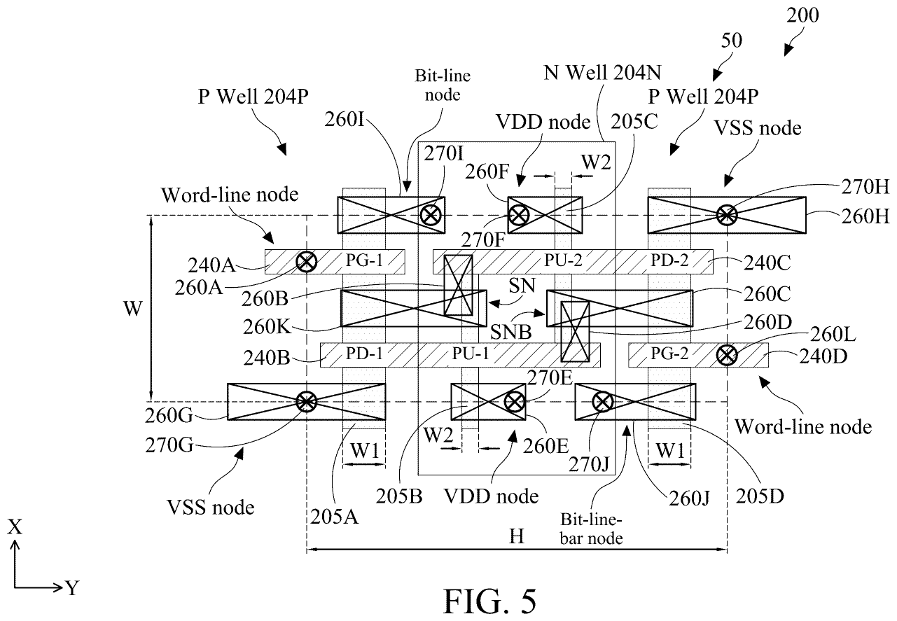

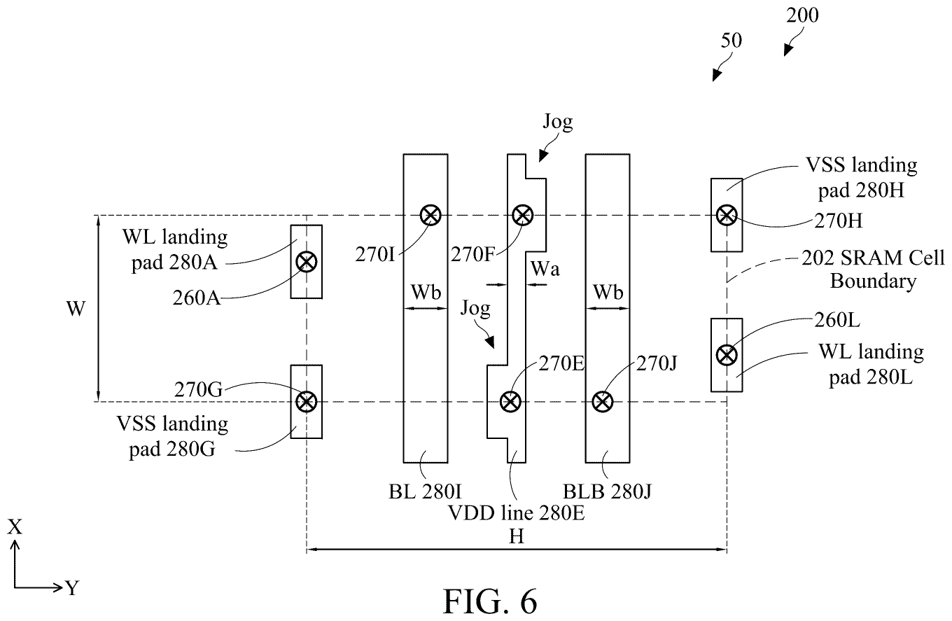

FIGS. 5 and 6 illustrate an exemplary layout 200 of the SRAM cell 50 as in FIG. 3, in which FIG. 5 illustrates the DL level, C0 level, and V0 level of the layout 200 and FIG. 6 illustrates V0 level and M0 level of the layout 200. The SRAM cell 50 has a cell boundary 202 represented by dotted lines in FIGS. 5 and 6. The cell boundary 202 is a rectangular box that is longer in the Y-direction than in the X-direction, for example, about 3.5 times to about 6 times longer. The first dimension of the cell boundary 202 along the X-direction is denoted as a cell width W, and the second dimension of the cell boundary 202 along the Y-direction is denoted as a cell height H. Where the SRAM cell 50 is repeated in a memory array, the cell width W may represent and be referred to as a memory cell pitch in the memory array along the X-direction, and the cell height H may represent and be referred to as a memory cell pitch in the memory array along the Y-direction. In the illustrated embodiment, the cell width W is two times a poly pitch. A poly pitch refers to a minimum center-to-center distance between two adjacent gate structures along the X-direction.

The SRAM cell 50 includes active regions 205 (including 205A, 205B, 205C, and 205D) that are oriented lengthwise along the X-direction, and gate structures 240 (including 240A, 240B, 240C and 240D) that are oriented lengthwise along the Y-direction perpendicular to the X-direction. The active regions 205B and 205C are disposed over an n-type well (or n-well) 204N. The active regions 205A and 205D are disposed over p-type wells (or p-wells) 204P that are on both sides of the n-well 204N along the Y-direction. The gate structures 240 engage the channel regions of the respective active regions 205 to form transistors. In that regard, the gate structure 240A engages the channel region of the active region 205A to form an n-type transistor as the pass-gate transistor PG-1; the gate structure 240B engages the channel region of the active region 205A to form an n-type transistor as the pull-down transistor PD-1 and engages the channel region of the active region 205B to form a p-type transistor as the pull-up transistor PU-1; the gate structure 240C engages the channel region of the active region 205D to form an n-type transistor as the pull-down transistor PD-2 and engages the channel region of the active region 205C to form a p-type transistor as the pull-up transistor PU-2; and the gate structure 240D engages the channel region of the active region 205D to form an n-type transistor as the pass-gate transistor PG-2. In the present embodiment, each of the channel regions is in the form of vertically-stacked nanostructures and each of the transistors PU-1, PU-2, PD-1, PD-2, PG-1, and PG-2 is a GAA transistor. Alternatively, each of the channel regions 215A-F is in the form of a fin and each of the transistors PU-1, PU-2, PD-1, PD-2, PG-1, and PG-2 is a FinFET transistor.

Different active regions in different transistors of the SRAM cell 50 may have different widths (e.g., dimensions measured in the Y-direction) in order to optimize device performance. In more detail, the active region 205A of the pull-down transistor PD-1 and the pass-gate transistor PG-1 has a width W1, the active region 205B of the pull-up transistor PU-1 has a width W2, the active region 205C of the pull-up transistor PU-2 has a width W2, and the active region 205D of the pass-gate PG-2 and the pull-down transistor PD-2 has a width W1. The widths W1 and W2 may also be measured in portions of the active regions corresponding to the channel regions. In other words, these portions of the active regions (from which the widths W1 and W2 are measured) are the channel regions (e.g., the vertically-stacked nanostructures of GAA devices) of the transistors. To optimize SRAM performance, in some embodiments, the width W1 is configured to be greater than the width W2 (W1>W2), as an effort to balance the speed among the n-type transistors and the p-type transistors. In some embodiments, a ratio of W1/W2 may range from about 1.1 to about 3.

The width W1 being larger than the width W2 increases strength of the n-type transistors in the SRAM cell 50, which leads to higher current handling capability of the SRAM cell 50. Such configuration of active regions is suitable for high-current applications (such SRAM cell is referred to as high-current SRAM cell), such as in level-1 and/or level-2 caches. In some other embodiments, the widths W1 and W2 may be the same (W1=W2). The reduced width W1 allows the SRAM cell 50 to have a smaller cell height H. Such configuration of active regions is suitable for high-density applications (such SRAM cell is referred to as high-density SRAM cell), such as in level-2 and/or level-3 caches. Taking the memory circuit 14 in FIG. 1 as an example, in one embodiment, the level-1 caches 20 include high-current SRAM cells, and all other caches include high-density SRAM cells; in another embodiment, the level-1 caches 20 and the level-2 cache 22 include high-current SRAM cells, and the level-3 cache 24 and the main memory 26 include high-density SRAM cells; in yet another embodiment, the level-1 caches 20, the level-2 cache 22, and the level-3 cache 24 include high-current SRAM cells, and the main memory 26 includes high-density SRAM cells.

The SRAM cell 50 further includes conductive features in the C0 level, V0 level, M0 level, and even higher metal levels (e.g., M1 level, M2 level, etc.). A gate contact 260A electrically connects a gate of the pass-gate transistor PG-1 (formed by gate structure 240A) to a first word line WL landing pad 280A. The first WL landing pad 280A is electrically coupled to a word line WL located at a higher metal level. A gate contact 260L electrically connects a gate of the pass-gate transistor PG-2 (formed by gate structure 240D) to a second word line WL landing pad 280L. The second WL landing pad 280L is electrically coupled to a word line WL located at a higher metal level. A source/drain (S/D) contact 260K electrically connects a drain region of the pull-down transistor PD-1 (formed on the active region 205A (which may include n-type epitaxial source/drain features)) and a drain region of the pull-up transistor PU-1 (formed on the active region 205B (which may include p-type epitaxial source/drain features)), such that a common drain of pull-down transistor PD-1 and pull-up transistor PU-1 form a storage node SN. A gate contact 260B electrically connects a gate of the pull-up transistor PU-2 (formed by gate structure 240C) and a gate of the pull-down transistor PD-2 (also formed by gate structure 240C) to the storage node SN. The gate contact 260B may be a butted contact abutting the S/D contact 260K. An S/D contact 260C electrically connects a drain region of the pull-down transistor PD-2 (formed on the active region 205D (which may include n-type epitaxial source/drain features)) and a drain region of the pull-up transistor PU-2 (formed on the active region 205C (which may include p-type epitaxial source/drain features)), such that a common drain of pull-down transistor PD-2 and pull-up transistor PU-2 form a complementary storage node SNB. A gate contact 260D electrically connects a gate of the pull-up transistor PU-1 (formed by the gate structure 222) and a gate of the pull-down transistor PD-1 (also formed by the gate structure 240B) to the complementary storage node SNB. The gate contact 260D may be a butted contact abutting the S/D contact 260C.

An S/D contact 260E and an S/D contact via 270E landing thereon electrically connect a source region of pull-up transistor PU-1 (formed on the active region 205B (which can include p-type epitaxial source/drain features)) to a VDD line 280E. The VDD line 280E is electrically coupled to a power supply voltage VDD. An S/D contact 260F and an S/D contact via 270F landing thereon electrically connect a source region of the pull-up transistor PU-2 (formed on the active region 205C (which may include p-type epitaxial source/drain features)) to the VDD line 280E. An S/D contact 260G and an S/D contact via 270G landing thereon electrically connect a source region of the pull-down transistor PD-1 (formed on the active region 205A (which may include n-type epitaxial source/drain features)) to a first VSS landing pad 280G. The first VSS landing pad 280G is electrically coupled to an electric ground VSS. An S/D contact 260H and an S/D contact via 270H landing thereon electrically connect a source region of the pull-down transistor PD-2 (formed on the active region 205D (which may include n-type epitaxial source/drain features)) to a second VSS landing pad 280H. The second VSS landing pad 280H is electrically coupled to an electric ground VSS. The S/D contact 260G and the S/D contact 260H may be device-level contacts that are shared by adjacent SRAM cells 50 (e.g., four SRAM cells 50 abutting at a same corner may share one S/D contact 260H). An S/D contact 260I and an S/D contact via 270I landing thereon electrically connect a source region of the pass-gate transistor PG-1 (formed on the active region 205A (which may include n-type epitaxial source/drain features)) to a bit line BL 280I. An S/D contact 260J and an S/D contact via 270J landing thereon electrically connect a source region of the pass-gate transistor PG-2 (formed on the active region 205D (which may include n-type epitaxial source/drain features)) to a complementary bit line (bit line bar) BLB 280J.

Conductive features in the C0 level, M0 level, and higher metal levels (e.g., M1 level, M2 layer, etc) are routed along a first routing direction or a second routing direction that is different than the first routing direction. For example, the first routing direction is the X-direction (and substantially parallel with the lengthwise direction of active regions 205A-205D) and the second routing direction is the Y-direction (and substantially parallel with the lengthwise direction of gate structures 240A-240D). In the depicted embodiment, source/drain contacts (260C, 260E, 260F, 260G, 260H, 260I, 260J) have longitudinal (lengthwise) directions substantially along the Y-direction (i.e., second routing direction), and butted contacts (260B, 260D) have longitudinal directions substantially along the X-direction (i.e., first routing direction). Metal lines of even-numbered metal layers (i.e., M0 level and M2 level) are routed along the X-direction (i.e., the first routing direction) and metal lines of odd-numbered metal layers (i.e., M1 level and M3 level) are routed along the Y-direction (i.e., the second routing direction). For example, in the M0 level as shown in FIG. 6, the bit line 280I, bit line bar 280J, VDD line 280E, VSS landing pad 280G, VSS landing pad 280H, word line landing pad 280A, word line landing pad 280L have longitudinal directions substantially along the X-direction. Further, since the metal lines in the same metal level (e.g., the M0 level) have the same longitudinal directions, the metal lines can be positioned in metal tracks arranged in parallel. A metal track may include one or more metal lines. For example, a metal track may include a single metal line that extends through the entire SRAM cell, or a metal track may include one or more local metal lines that do not extend through the entire SRAM cell.

The illustrated metal lines are generally rectangular-shaped (i.e., each has a length greater than its width), but the present disclosure contemplates metal lines having different shapes and/or combinations of shapes to optimize and/or improve performance (e.g., reduce resistance) and/or layout footprint (e.g., reduce density). For example, the VDD line 280E may optionally have jogs added as shown in FIG. 6. The jog portion of the VDD line 280E has a larger width than other portion of the VDD line 280E. The jog may add about 1% to about 50% extra width to the VDD line 280E. The jogs are added to interconnection regions (areas) of the VDD line 280E to increase cross-sectional areas of the interconnection regions. Increasing cross-sectional areas of the interconnection regions of the VDD line 280E allows for increasing cross-sectional areas of the S/D contact vias 270E and 270F in the V0 level, which reduces routing resistance between the connection of the VDD line 280E and respective source/drain contacts (and thus to underlying source/drain regions).

“Landing pad” generally refers to metal lines in metal layers that provide intermediate, local interconnection for the SRAM cell, such as (1) an intermediate, local interconnection between a device-level feature (e.g., gate or source/drain) and a bit line, a bit line bar, a word line, a voltage line or (2) an intermediate, local interconnection between bit lines, word lines, or voltage lines. For example, the VSS landing pad 280G is connected to source/drain contact 260G of the transistor PD-1 and further connected to a VSS line located in a higher metal level, the VSS landing pad 280H is connected to source/drain contact 260H of the transistor PD-2 and further connected to a VSS line located in a higher metal level, the WL landing pad 280A is connected to a gate of the transistor PG-1 and further connected to a word line WL located in a higher metal level, and the WL landing pad 280L is connected to a gate of the transistor PG-2 and further connected to a word line WL located in a higher metal level. Landing pads have longitudinal dimensions that are large enough to provide a sufficient landing area for their overlying vias (and thus minimize overlay issues and provide greater patterning flexibility). In the depicted embodiment, landing pads have longitudinal dimensions that are less than dimensions of the SRAM cell 50, such as dimensions along the X-direction that are less than cell width W and dimensions along the Y-direction that are less than cell height H. As a comparison to the landing pads, the bit line 280I, the bit line bar 280J, and the VDD line 280E have longitudinal dimensions along the X-direction that are greater than cell width W of the SRAM cell 50. As they travel through the entire SRAM cell 50 along the X-direction, the bit line 280I, the bit line bar 280J, and the VDD line 280E at the M0 level are also referred to as global metal lines, while others are referred to as local metal lines (including landing pads). In some embodiments, a length of each of the bit line 280I, the bit line bar 280J, and the VDD line 280E is sufficient to allow electrical connection of multiple SRAM cells in a column (or a row) to the respective global metal line.

The metal lines (global metal lines and local metal lines) in the SRAM cell 50 at the M0 level may have different widths. For example, the VDD line 280E has a width Wa, and the bit line 280I and bit line bar 280J each have a width Wb. In some embodiments, the width Wb is larger than the width Wa(Wb>Wa). Having the largest width reserved to the bit line 280I and bit line bar 280J allows the signal lines in the bit line pair to generally benefit from a reduced resistance and thus a reduced voltage drop along the signal lines. In some embodiments, a ratio of width Wb to width Wa(i.e., Wb/Wa) is about 1.1 to about 2. In some embodiments, the width Wa is larger than the width Wb (Wa>Wb). Having the largest width reserved to the VDD line 280E allows the VDD line 280E to generally benefit from a reduced resistance and thus a reduced voltage drop along the power supply lines. In some embodiments, a ratio of width Wa to width Wb (i.e., Wa/Wb) is about 1.1 to about 2.

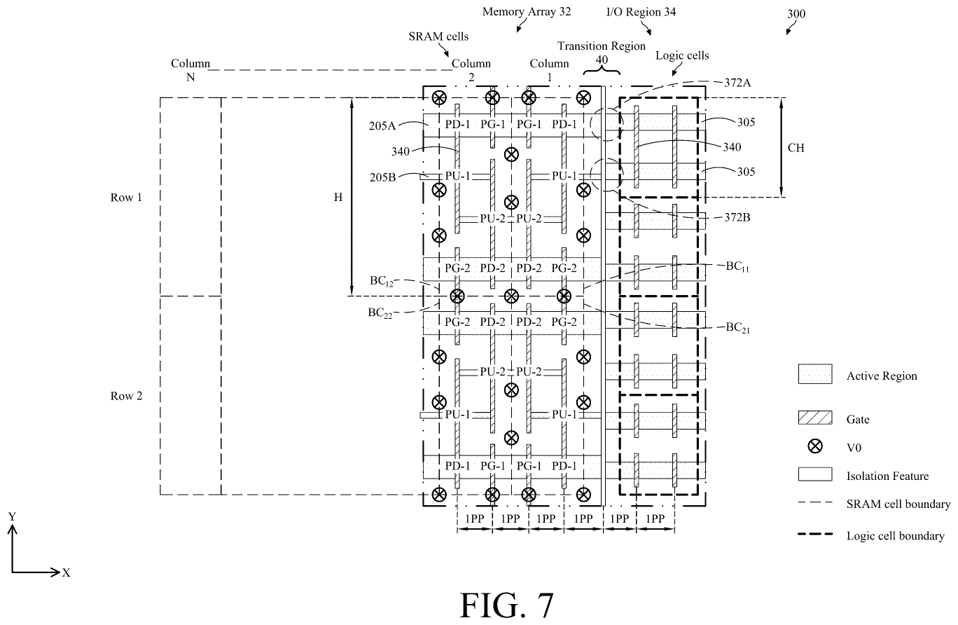

FIG. 7 illustrates the DL level and V0 level of a layout 300 of a portion of the memory macro 30 (FIG. 2), which includes first two rows (Rows 1-2) of the memory array 32 and a portion of the logic cells in the I/O circuit (or referred to as I/O region) 34. FIG. 7 has been simplified for the sake of clarity to better understand the inventive concepts of the present disclosure. For example, active regions, gate structures, gate-cut isolation features, and vias at the V0 level in the SRAM cells of the first two columns and first two rows (i.e., BC₁₁, BC₁₂, BC₂₁, BC₂₂) of the memory array 32 (FIG. 2) are shown, while numerous other features are omitted in FIG. 7.

The SRAM cells in the memory array 32 include a first type of active regions (e.g., 205A and 205B), and the logic cells in the I/O region 34 includes a second type of active regions (e.g., 305). The active regions in the memory array 32 are arranged along the Y-direction and oriented lengthwise in the X-direction. As discussed above, the active regions (e.g., 205A and 205B) may have different widths and/or the same width (e.g., W1 and W2 in FIG. 5). The active regions in the I/O region 34 are arranged along the Y-direction and oriented lengthwise in the X-direction. In the illustrated embodiment, the active regions 305 are evenly distributed along the Y-direction and each have a uniform width. The memory macro further includes gate structures 340 arranged along the X-direction and extending lengthwise in the Y-direction. In the illustrated embodiment, the gate structures 340 are evenly distributed along the X-direction with a uniform distance between two adjacent gate structures 340. The uniform distance is denoted as a gate pitch or a poly pitch (“PP”). The SRAM cell width W can also be measured by the number of poly pitches. In the illustrated embodiment, the SRAM cell width W is two times a poly pitch. The memory array 32's width along the X direction can also be measured by the number of poly pitches. Since each SRAM cell has a width W of two times a poly pitch, for having a number of N SRAM cells in a row, the memory array 32 has a width of 2*N poly pitches.

The gate structures 340 intersect the active regions in forming transistors. Transistors formed at the intersections of the active regions and the gate structures 340 within the memory array 32 are devoted to form SRAM cells. The transistors formed at the intersections of the active regions and the gate structures 340 within the I/O region 34 are devoted to form logic cells. In the illustrated embodiment, the transistors in the SRAM array 32 form a plurality of SRAM cells, such as SRAM cells BC₁₁, BC₁₂, BC₂₁, BC₂₂ (collectively, SRAM cells BC). Each SRAM cell BC in the array may use the layout 200 of the SRAM cell 50 as depicted in FIG. 5. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell BC₁₂ is a duplicate cell for the SRAM cell BC₁₁ but flipped over the Y-axis; the SRAM cell BC₂₂ is a duplicate cell for the SRAM cell BC₁₂ but flipped over the X-axis; and the SRAM cell BC₂₁ is a duplicate cell for the SRAM cell BC₁₁ but flipped over the X-axis.

Some active regions extend through multiple SRAM cells in a row. For example, the active region for the transistors PD-1, PG-1 in the SRAM cell BC₁₁ extends through the SRAM cell BC₁₂ as the active region for its transistors PG-1, PD-1 and further through the other SRAM cells BC in the Row 1; the active region for the transistors PG-2, PD-2 in the SRAM cell BC₁₁ extends through the SRAM cell BC₁₂ as the active region for its transistors PD-2, PG-2 and further through the other SRAM cells BC in the Row 1; and the active region for the transistors PU-2 in the SRAM cell BCH extends into the SRAM cell BC₁₂ as the active region for its transistors PU-2. The active regions in the SRAM cells BC₂₁, BC₂₂ are similarly arranged. The vias at the V0 level in the SRAM cells are also illustrated in FIG. 7.

In the illustrated embodiment, the transistors in the I/O region 34 form a plurality of logic cells. The logic cells may be standard cells, such as inventor (INV), AND, OR, NAND, NOR, Flip-flip, SCAN and so on. The logic cells implement various logic functions to the SRAM cells BC. The logic functions of the logic cells include, for example, write and/or read decoding, word line selecting, bit line selecting, data driving and memory self-testing. As depicted, each logic cell has a logic cell height CH, which is half of the SRAM cell height H. Therefore, two logic cells have a boundary with opposing edges aligned with opposing edges of the boundary of one SRAM cell with the edges spaced in the Y-direction and each edge extending in the X-direction.

Between the opposing boundary lines of the SRAM cells in the memory array 32 and the logic cells in the I/O region 34 is an active region transition region 40, or simply as the transition region. Inside the transition region 40, the active regions 205A extending from the edge column of the SRAM cells meet the active regions 305 extending from the edge column of the logic cells. Since a pair of the active regions 205A, 305 that meet may have different widths, a jog is created at where the active regions 205A, 305 meet. A jog refers to a junction where two segments of different widths meet each other. For example, in the region 372A represented by a dotted circle, a relatively wide active region 205A meets a relatively narrow active region 305, creating a jog. The upper edges of the active regions 205A, 305 align, while the lower edges of the active regions 205A, 305 creates a step profile. Similarly, in the region 372B represented by another dotted circle, a relatively narrow active region 205B meets a relatively wide active region 305, creating another job. The lower edges of the active regions 205B, 305 align, while the upper edges of the active regions 205B, 305 creates a step profile.

As depicted in the layout 300, the transition region 40 has a span of one poly pitch between the opposing boundary lines of the SRAM cells and the logic cells along the X-direction. In the transition region 40, a dielectric feature (or isolation feature) 374 is oriented lengthwise in the Y-direction and provides isolation between the active regions in the memory array 32 and the I/O region 34. The dielectric feature 374 overlaps with the jogs. In the exemplary layout 300, the dielectric feature 374 continuously extends along the boundary lines of the SRAM cells and the logic cells in the Y-direction. In other words, the dielectric feature 374 is taller the SRAM cell height H.

The dielectric feature 374 may be formed in a continuous-poly-on-diffusion-edge (CPODE) process. In a CPODE process, a polysilicon gate is replaced by a dielectric feature. For purposes of this disclosure, a “diffusion edge” may be equivalently referred to as an active edge, where for example an active edge abuts adjacent active regions. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion or full of the otherwise continuous gate structure and is confined between the opposing gate spacers of the replaced portion of the gate structure. The dielectric feature 374 is also referred to as a gate-cut feature or a CPODE feature. Since the CPODE feature 374 is formed by replacing the previously-formed polysilicon gate structures, the CPODE feature 374 inherits the arrangement of the gate structures 340. That is, the CPODE feature 374 may have the same width as the gate structures 340 and the same pitch as the gate structures 340.

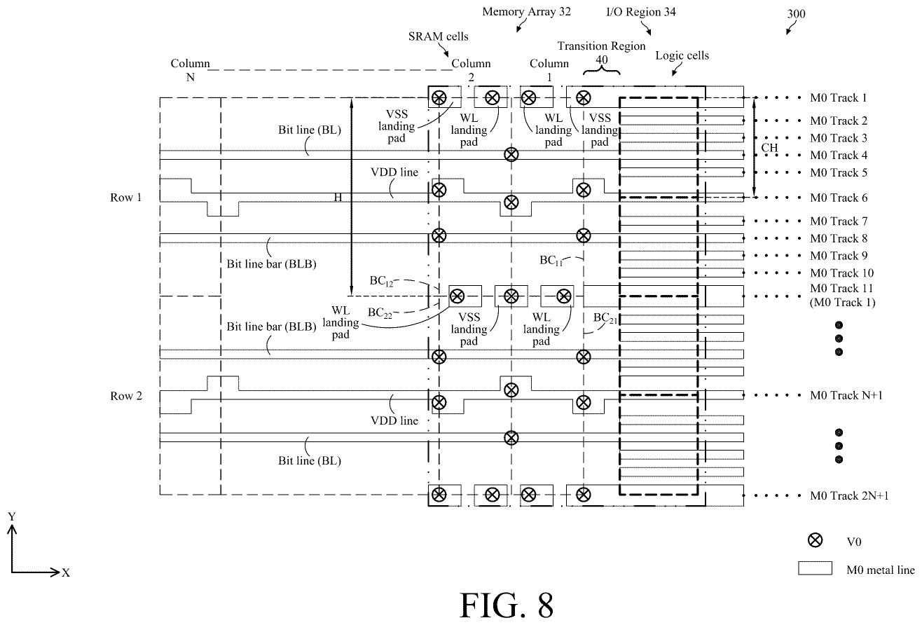

FIG. 8 illustrates the V0 level and M0 level of the layout 300 of the portion of the memory macro 30 (FIG. 2), which includes first two rows (Rows 1-2) of the memory array 32 and a portion of the logic cells in the I/O circuit 34. At the M0 level, the I/O region 34 includes a plurality of metal tracks arranged in parallel. Particularly, in the illustrated embodiment of the layout 300, two abutting logic cells include eleven metal tracks arranged in order from first (M0 Track 1) to eleventh (M0 Track 11) along the Y-direction. The center lines of the metal tracks are represented by the dashed lines in FIG. 8.

The metal lines in the SRAM cells are aligned with the metal tracks in the I/O region 34, allowing the metal lines in the logic cells to extend into the SRAM cells. Thus, there is no need for edge cells between the SRAM cells and the logic cells to provide metal transitions. In the M0 Track 1, a VSS line extends into the SRAM cell BC₁₁ and merges with the VSS landing pad. In the M0 Track 2, the metal line as a signal line in the logic cell remains in the boundary of the respective logic cell. In the M0 Track 3, the metal line as a signal line in the logic cell remains in the boundary of the respective logic cell. In the M0 Track 4, the metal line as the bit line BL in the logic cell also extends into and through the SRAM cells as a bit line BL for multiple SRAM cells in the same row. In the M0 Track 5, the metal line as a signal line in the logic cell remains in the boundary of the respective logic cell. In the M0 Track 6, the metal line as a VDD line in the logic cell also extends into and through the SRAM cells as a VDD line for multiple SRAM cells in the same row. In the M0 Track 7, the metal line as a signal line in the logic cell remains in the boundary of the respective logic cell. In the M0 Track 8, the metal line as the bit line bar BLB in the logic cell also extends into and through the SRAM cells as a bit line bar BLB for multiple SRAM cells in the same row. In the M0 Track 9, the metal line as a signal line in the logic cell remains in the boundary of the respective logic cell. In the M0 Track 10, the metal line as a signal line in the logic cell remains in the boundary of the respective logic cell. In the M0 Track 11, the metal line as a VSS line in the logic cell may extend through the boundary of the respective logic cell but does not contact the word line WL landing pad.

The boundary of an SRAM cell may abut the boundary of one or two logic cells. The one or two logic cells provide 2*N+1 metal tracks, where N is an integer. The metal line in the center metal track (the (N+1)th metal track) extends into the SRAM cell as a common VDD line for both the SRAM cell and the one or two logic cells. The two metal lines in the two metal tracks in equal spacing from the center metal track extend into the SRAM cell as a bit line BL and a bit line bar BLB, respectively, for both the SRAM cell and the one or two logic cells. The two metal lines in the first and the (2*N+1)th metal tracks extend through the boundary of the one or two logic cells and connect to one of the VSS landing pads in the SRAM cell.

In the illustrated embodiment, the metal lines in the metal tracks 4 and 8 extend from the logic cells and through the SRAM cells in the same row as a bit line BL and a bit line bar BLB, respectively. Alternatively, depending on the layout, it may be the metal lines in the metal tracks 2 and 10, or the metal tracks 3 and 9, or the metal tracks 5 and 7 that extend from the logic cells and through the SRAM cells as a bit line BL and a bit line bar BLB, respectively. In the context, the bit line BL and the complementary bit line BLB may also be collectively referred to as bit lines if not separately indicated.

In semiconductor memory design, one uniform bit line width is generally employed across memory arrays of different sizes. However, preferences for bit line width may differ between small and large memory arrays. For smaller arrays, such as L1 caches, narrower bit lines help achieving reduced parasitic capacitance, thereby enabling faster access times and lower power consumption. In contrast, larger memory arrays, like L2 caches, wider bit lines help achieving reduced resistance, which facilitates maintaining signal integrity over longer distances.

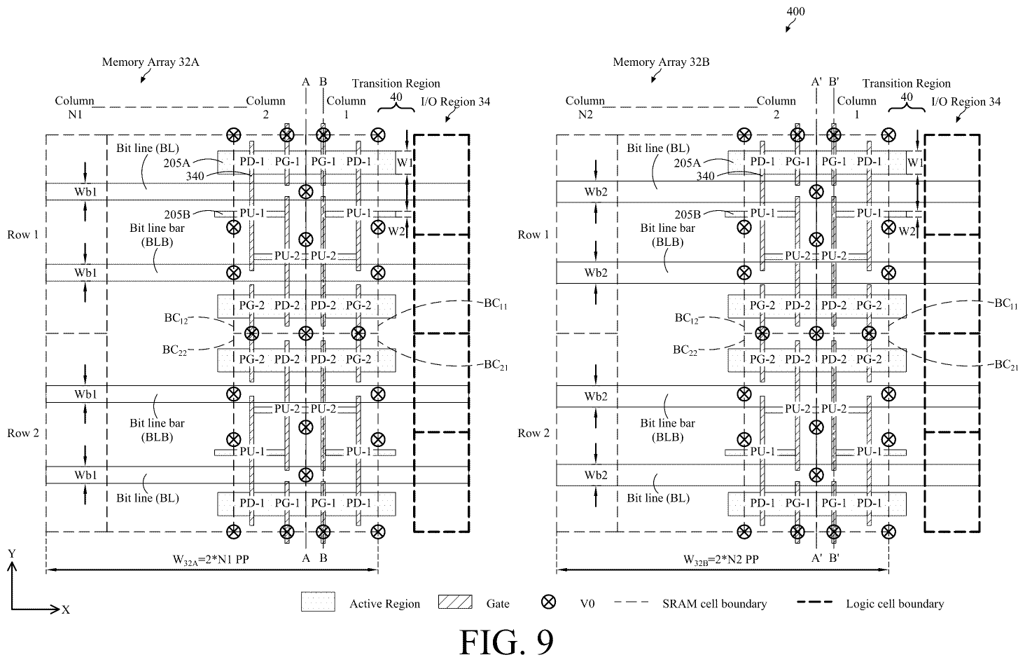

FIG. 9 illustrates a layout 400 showing a part of the memory circuit 14 (FIG. 1), which has a first cache including a first memory array 32A and a second cache including a second memory array 32B. The first memory array 32A includes memory cells arranged in M1 rows and N1 columns, and the second memory array 32B includes memory cells arranged in M2 rows and N2 columns. For simplicity, only the first two rows (Rows 1-2) of the first memory array 32A and the second memory array 32B are illustrated in FIG. 9. Also for simplicity, only active regions, gate structures, vias at the V0 level in the SRAM cells of the first two columns and first two rows (i.e., BC₁₁, BC₁₂, BC₂₁, BC₂₂), and bit lines (BL and BLB) for the first two rows of the respective memory arrays are shown, while numerous other features are omitted in FIG. 9.

The first memory array 32A is a smaller array, and the second memory array 32B is a larger array (M1<M2 and N1<N2). State differently, in the first memory array 32A, a single bit line (either BL or BLB) is shared by less memory cells (N1) in the same row, and in the second memory array 32B, a single bit line (cither BL or BLB) is shared by more memory cells in the same row (N2). The smaller first memory array 32A may reside in a first cache that is generally smaller and faster, such as a level-1 cache or a level-2 cache, and the larger second memory array 32B may reside in a second cache that is generally larger and slower, such as a level-2 cache or a level-3 cache. In one example, the first cache is a level-1 cache and employs the first memory array 32A with each bit line feeding 32 or 64 memory cells in the same row (N1=32 or 64), and the second cache is a level-2 cache and employs the second memory array 32B with each bit line feeding 128 or more than 128 memory cells in the same row (N2=128 or N2>128).

In the illustrated embodiment, a single SRAM cell has a width along the X direction that is two times a poly pitch (PP). By having a number of N1 SRAM cells in a row, the first memory array 32A has a width W_{32A} of 2*N1 poly pitches. By having a number of N2 SRAM cells in a row, the second memory array 32B has a width W_{32B} of 2*N2 poly pitches. The height of a single SRAM cell along the Y direction depends on whether it is a high-current design or a high-density design. As discussed above, having a width W1 of the active region 205A being larger than a width W2 of the active region 205B (W1>W2) allows each SRAM cell to handle more current; in contrast, having a width W1 of the active region 205A being equal to a width W2 of the active region 205B (W1=W2) allows each SRAM cell to be more compact, which saves area. In the illustrated embodiment, the first memory array 32A and the second memory array 32B have the same high-current SRAM cells with W1>W2. Alternatively, the first memory array 32A and the second memory array 32B may have the same high-density SRAM cells with W1=W2, or the first memory array 32A may have the high-current SRAM cells with W1>W2 and the second memory array 32B may have the high-density SRAM cells with W1=W2.

The bit lines in the first memory array 32A have a uniform width Wb1, and the bit lines in the second memory array 32B have a uniform width Wb2 that is larger than Wb1 (Wb2>Wb1). In a smaller memory array with fewer SRAM cells in a row, the bit line length is already shorter and thus the voltage drop along the bit lines is less of a concern, while the bit line width affects parasitic capacitance which may hinder the circuit speed. The smaller width Wb1 reduces parasitic capacitance, which improves circuit speed and reduces power consumption, without compromising the voltage headroom along the bit lines. In contrast, in a larger memory array with more SRAM cells in a row, the bit line length is longer and thus the voltage drop along the bit lines is a bigger concern. The larger width Wb2 reduces resistance, which increases voltage headroom along the bit lines and improves signal integrity. Even though the larger width Wb2 introduces more parasitic capacitance, as the larger memory array is employed in a relatively slower cache, circuit speed being slightly compromised is less of a concern.

In various embodiments, a ratio between the larger width Wb2 and the width W1 of the active region 205A in a high-current SRAM cell (i.e., a SRAM cell with W1>W2) ranges between about 1.5 and about 5 (1.5<Wb2/W1≤5), and a ratio between the smaller width Wb1 and the width W1 of the active region 205A in a high-current SRAM cell ranges between about 1 and about 1.5 (1<Wb1/W1≤1.5). These ranges are not trivial or arbitrary. If Wb2/W1 is smaller than about 1.5, there may be not enough voltage headroom for a long bit line; if Wb2/W1 is larger than about 5, the bit line may be too wide and intersect adjacent power/signal lines; if Wb1/W1 is smaller than about 1, the bit line may become too resistive and slow down circuit speed reversely; and if Wb1/W1 is larger than about 1.5, the parasitic capacitance may be too large and the circuit speed may be compromised. In furtherance of some embodiments, the semiconductor memory design may optionally provide a third bit line width Wb0 that is even smaller than Wb1 (Wb0<Wb1<Wb2). The bit line width Wb0 may be employed in a memory array (not shown in FIG. 9) for a micro cache. A micro cache may be a type of level-1 cache that has the smallest memory array and the fastest speed in the memory circuit 14. In a micro cache, each bit line may only feed 16 or 32 SRAM cells in the same row. If the third bit line width Wb0 is provided in the semiconductor memory design, a ratio between the smallest width Wb0 and the width W1 of the active region 205A in a high-current SRAM cell ranges between about 0.3 and about 1 (0.3<Wb0/W1≤1) in some embodiments. Again, these ranges are not trivial or arbitrary. If Wb0/W1 is smaller than about 0.3, the bit line may become too resistive and slow down circuit speed of a micro cache reversely; and if Wb0/W1 is larger than about 1, the parasitic capacitance may be too large and hinder circuit speed of a micro cache. Similarly, in various embodiments, a ratio between the larger width Wb2 and the width W1 of the active region 205A in a high-density SRAM cell (i.e., a SRAM cell with W1=W2) ranges between about 3 and about 15 (3<Wb2/W1≤15), a ratio between the smaller width Wb1 and the width W1 of the active region 205A in a high-density SRAM cell ranges between about 2 and about 3 (2<Wb1/W1≤3), and a ratio between the smallest width Wb0 (if presented) and the width W1 of the active region 205A in a high-density SRAM cell ranges between about 0.5 and about 2 (0.5<Wb1/W1≤2).

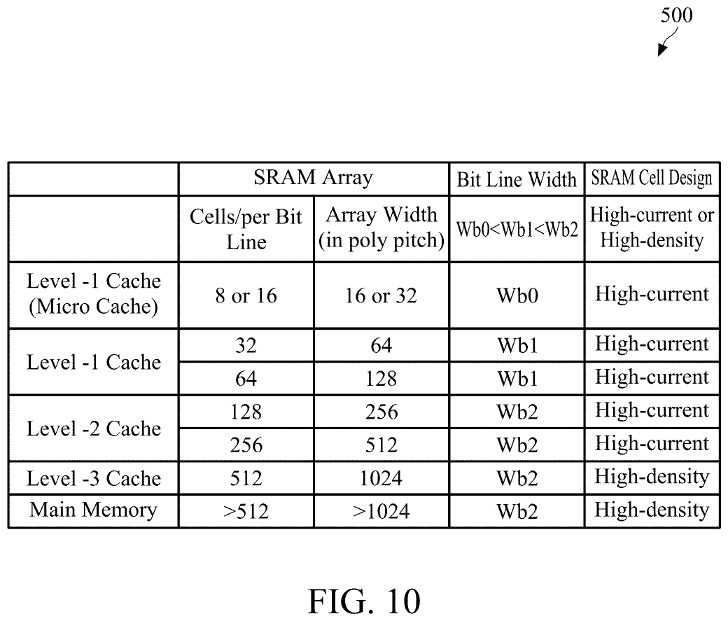

FIG. 10 is a table 500 showing a specific example of various SRAM arrays and corresponding various bit line widths that may exist in a memory macro 30 (FIG. 2). The table 500 is merely an example and is not intended to be limiting. The exemplary memory macro 30 includes a micro cache. The micro cache employs an SRAM array with each bit line coupled to 8 or 16 memory cells in the same row. The SRAM array has an array width of 16 or 32 poly pitches. Each bit line has a bit line width Wb0, which is the smallest among the available bit line widths. The memory cells in the SRAM array are based on high-current design. The exemplary memory macro 30 includes a level-1 cache of a first type. The first type level-1 cache employs an SRAM array with each bit line coupled to 32 memory cells in the same row. The SRAM array has an array width of 64 poly pitches. Each bit line has a bit line width Wb1, which is in the middle among the available bit line widths. The memory cells in the SRAM array are based on high-current design. The exemplary memory macro 30 includes a level-1 cache of a second type. The second type level-1 cache employs an SRAM array with each bit line coupled to 64 memory cells in the same row. The SRAM array has an array width of 128 poly pitches. Each bit line has a bit line width Wb1, which is in the middle among the available bit line widths. The memory cells in the SRAM array are based on high-current design. The exemplary memory macro 30 includes a level-2 cache of a first type. The first type level-2 cache employs an SRAM array with each bit line coupled to 128 memory cells in the same row. The SRAM array has an array width of 256 poly pitches. Each bit line has a bit line width Wb2, which is in the largest among the available bit line widths. The memory cells in the SRAM array are based on high-current design. The exemplary memory macro 30 includes a level-2 cache of a second type. The second type level-2 cache employs an SRAM array with each bit line coupled to 256 memory cells in the same row. The SRAM array has an array width of 512 poly pitches. Each bit line has a bit line width Wb2, which is in the largest among the available bit line widths. The memory cells in the SRAM array are based on high-current design. The exemplary memory macro 30 includes a level-3 cache. The level-3 cache employs an SRAM array with each bit line coupled to 512 memory cells in the same row. The SRAM array has an array width of 1024 poly pitches. Each bit line has a bit line width Wb2, which is in the largest among the available bit line widths. The memory cells in the SRAM array are based on high-density design. The exemplary memory macro 30 includes a main memory. The main memory employs an SRAM array with each bit line coupled to more than 512 memory cells in the same row. The SRAM array has an array width of more than 1024 poly pitches. Each bit line has a bit line width Wb2, which is in the largest among the available bit line widths. The memory cells in the SRAM array are based on high-density design.

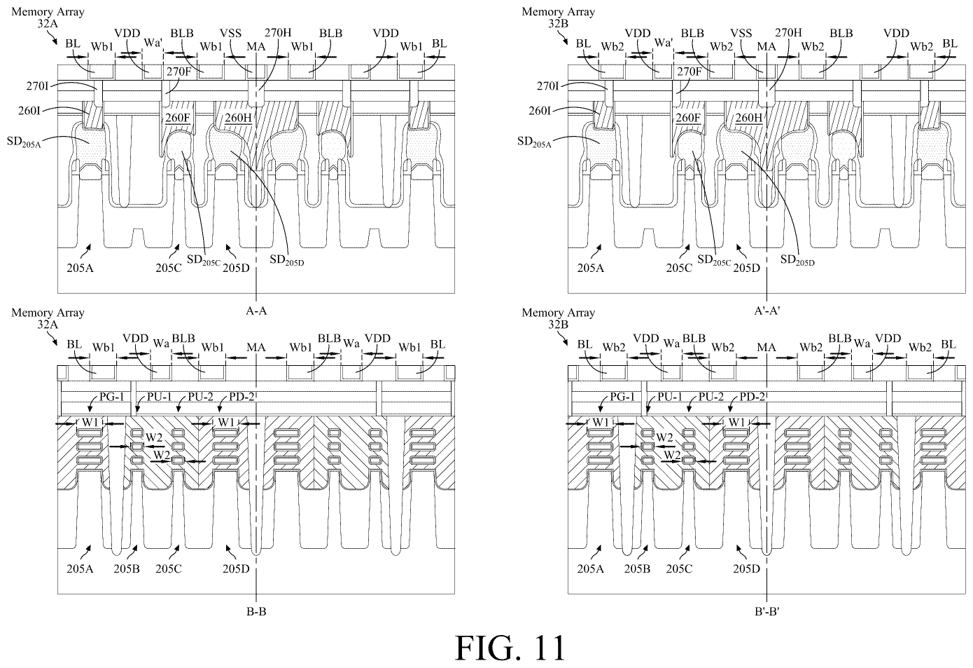

FIG. 11 illustrates fragmentary cross-sectional views along cross sections A-A, B-B, A′-A′, and B′-B′ in FIG. 9, respectively. As shown in FIG. 9, the cross-section A-A cuts through source/drain regions along a cell boundary between the memory cells BC₁₁ and BC₁₂ and between the memory cells BC₂₁ and BC₂₂ in the first memory array 32A; the cross-section B-B cuts through the gate structures 340 of the memory cells BC₁₁ and BC₂₁ in the first memory array 32A; the cross-section A′-A′ cuts through source/drain regions along a cell boundary between the memory cells BC₁₁ and BC₁₂ and between the memory cells BC₂₁ and BC₂₂ in the second memory array 32B; and the cross-section B′-B′ cuts through the gate structures 340 of the memory cells BC₁₁ and BC₂₁ in the second memory array 32B. In FIG. 11, each cross section is symmetric with respect to a mirror axis MA.

Reference is now made to the cross sections A-A and B-B collectively, which are located in the first memory array 32A. The active region 205A includes a plurality of nanostructures as channel layers vertically stacked above a fin-shape base. The channel layers provide the channel region for the n-type pass-gate transistor PG-1. Measured on the topmost channel layer, the active region 205A have a width W1. In the source/drain region, a source/drain epitaxial feature SD_{205A} is epitaxially grown on the fin-shape base of the active region 205A. The source/drain epitaxial feature SD_{205A} is electrically coupled to the bit line BL through S/D contact 260I and S/D contact via 270I. The bit line BL has a first width Wb1, which is smaller than a second width Wb2 in the second memory array 32B. The active region 205B includes a plurality of nanostructures as channel layers vertically stacked above a fin-shape base. The channel layers provide the channel region for the p-type pull-up transistor PU-1. Measured on the topmost channel layer, the active region 205B have a width W2. In a high-current SRAM cell, the width W2 is smaller than the width W1 (W2<W1); in a high-density SRAM cell, the width W2 may equal the width W1 (W1=W2). The active region 205C includes a plurality of nanostructures as channel layers vertically stacked above a fin-shape base. The channel layers provide the channel region for the p-type pull-up transistor PU-2. Measured on the topmost channel layer, the active region 205C have a width W2. In the source/drain region, a source/drain epitaxial feature SD_{205C} is epitaxially grown on the fin-shape base of the active region 205C. The source/drain epitaxial feature SD_{205C} is electrically coupled to the VDD line through S/D contact 260F and S/D contact via 270F. The cross section A-A may cut along a jog portion of the VDD line, which has a width Wa′ that is larger than a width Wa of the VDD line in the cross section B-B. The width Wb1 of the bit line BL may be wider than both the widths Wa and Wa′ as illustrated; alternatively, the width Wb1 may be larger than the width Wa but smaller than the width Wa′ of the jog portion. The selection of widths may dependent on specific circuit performance needs. The active region 205D includes a plurality of nanostructures as channel layers vertically stacked above a fin-shape base. The channel layers provide the channel region for the n-type pull-down transistor PD-2. Measured on the topmost channel layer, the active region 205D have a width W1. In the source/drain region, a source/drain epitaxial feature SD_{205D} is epitaxially grown on the fin-shape base of the active region 205D. The source/drain epitaxial feature SD_{205D} is electrically coupled to the VSS landing pad through S/D contact 260H and S/D contact via 270H. The mirror image placement of the SRAM cells allows a larger S/D contact 260H lands on the source/drain epitaxial feature SD_{205D}. Cross sections A-A and B-B also depicts bit line bar BLB disposed between the VDD line and the VSS landing pad. The bit line bar BLB has the same width Wb1 as the bit line BL.

Reference is now made to the cross sections A′-A′ and B′-B′ collectively, which are located in the second memory array 32B. The active region 205A includes a plurality of nanostructures as channel layers vertically stacked above a fin-shape base. The channel layers provide the channel region for the n-type pass-gate transistor PG-1. Measured on the topmost channel layer, the active region 205A have a width W1. In the source/drain region, a source/drain epitaxial feature SD_{205A} is epitaxially grown on the fin-shape base of the active region 205A. The source/drain epitaxial feature SD_{205A} is electrically coupled to the bit line BL through S/D contact 260I and S/D contact via 270I. The bit line BL has a second width Wb2, which is larger than a first width Wb1 in the first memory array 32A. The active region 205B includes a plurality of nanostructures as channel layers vertically stacked above a fin-shape base. The channel layers provide the channel region for the p-type pull-up transistor PU-1. Measured on the topmost channel layer, the active region 205B have a width W2. In a high-current SRAM cell, the width W2 is smaller than the width W1 (W2<W1); in a high-density SRAM cell, the width W2 may equal the width W1 (W1=W2). The active region 205C includes a plurality of nanostructures as channel layers vertically stacked above a fin-shape base. The channel layers provide the channel region for the p-type pull-up transistor PU-2. Measured on the topmost channel layer, the active region 205C have a width W2. In the source/drain region, a source/drain epitaxial feature SD_{205C} is epitaxially grown on the fin-shape base of the active region 205C. The source/drain epitaxial feature SD_{205C} is electrically coupled to the VDD line through S/D contact 260F and S/D contact via 270F. The cross section A-A may cut along a jog portion of the VDD line, which has a width Wa′ that is larger than a width Wa of the VDD line in the cross section B-B. The width Wb2 of the bit line BL may be wider than both the widths Wa and Wa′ as illustrated; alternatively, the width Wb2 may be larger than the width Wa but smaller than the width Wa′ of the jog portion. The selection of widths may dependent on specific circuit performance needs. The active region 205D includes a plurality of nanostructures as channel layers vertically stacked above a fin-shape base. The channel layers provide the channel region for the n-type pull-down transistor PD-2. Measured on the topmost channel layer, the active region 205D have a width W1. In the source/drain region, a source/drain epitaxial feature SD_{205D} is epitaxially grown on the fin-shape base of the active region 205D. The source/drain epitaxial feature SD_{205D} is electrically coupled to the VSS landing pad through S/D contact 260H and S/D contact via 270H. The mirror image placement of the SRAM cells allows a larger S/D contact 260H lands on the source/drain epitaxial feature SD_{205D}. Cross sections A′-A′ and B′-B′ also depicts bit line bar BLB disposed between the VDD line and the VSS landing pad. The bit line bar BLB has the same width Wb2 as the bit line BL.

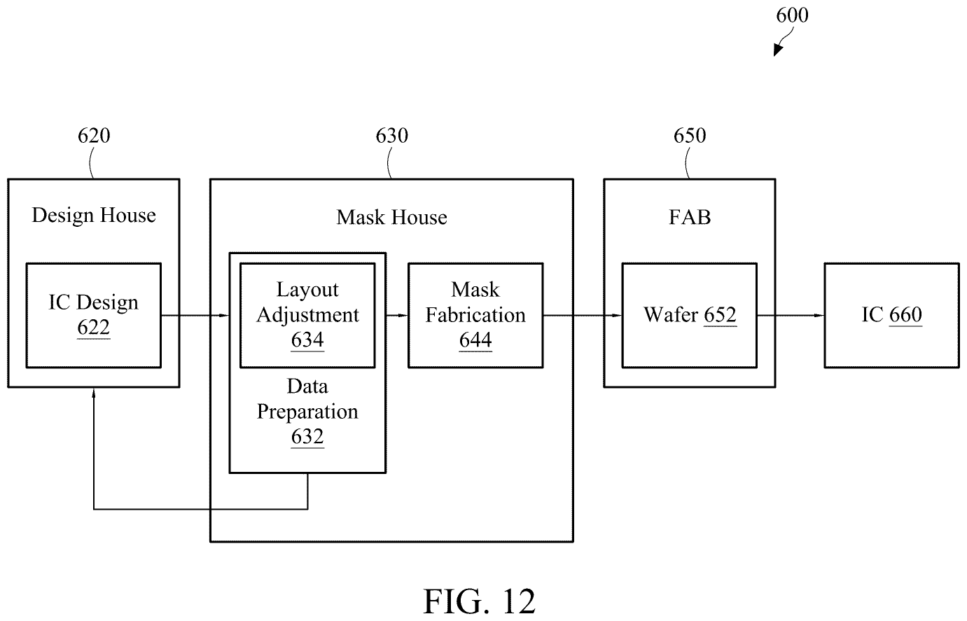

FIG. 12 is a simplified block diagram of an embodiment of an IC manufacturing system 600 and an IC manufacturing flow associated therewith. The IC manufacturing system 600 includes a plurality of entities, such as a design house 620, a mask house 630, and an IC manufacturer 650 (i.e., a fab), that interact with one another in the design, development, and manufacturing cycles and/or services related to manufacturing an IC device 660. The various entities are connected by a communications network, which may be a single network or a variety of different networks, such as an intranet and the Internet, and may include wired and/or wireless communication channels. Each entity may interact with other entities and may provide services to and/or receive services from the other entities. One or more of the design house 620, mask house 630, and IC manufacturer 650 may be owned by separate companies or by a single company, and may even coexist in a common facility and use common resources.

The design house (or design team) 620 generates an IC design layout (or IC layout) 622. The IC design layout 622 includes various geometrical patterns (e.g., polygons representing metal lines) designed for the IC device 660. The geometrical patterns correspond to IC features in one or more semiconductor layers that make up the IC device 660. Exemplary IC features include active regions, gate electrodes, source and drain features, isolation features, metal lines, contact plugs, vias, and so on. The design house 620 implements appropriate design procedures to form the IC design layout 622. The design procedures may include logic design, physical design, place and route, and/or various design checking operations. The IC design layout 622 is presented in one or more data files having information of the geometrical patterns. For example, the IC design layout 622 can be expressed in a GDSII file format or DFII file format. In the present embodiment, the IC device 660 may include a memory circuit, such as the memory circuit 14 in FIG. 1. However, the IC design layout 622 as expressed in a GDSII file format or DFII file format may have the geometrical patterns representing bit lines as one uniform bit line width. That is, examining the IC design layout 622 alone would not reveal there are multiple bit line width options for different memory array sizes.

The mask house 630 uses the IC design layout 622 to manufacture a set of masks to be used for fabricating the various layers of the IC device 660 according to the IC design layout 622. The mask house 630 performs data preparation 632 and mask fabrication 644. The data preparation 632 translates the IC design layout 622 into a form that can be physically written by a mask writer. The mask fabrication 644 fabricates the set of masks (photomask or reticle).

In the present embodiment, the data preparation 632 includes a layout adjustment 634 which is configured to adjust metal line widths corresponding to bit lines. The layout adjustment 634 adjusts bit line widths based on thresholds set for memory array sizes. For example, a threshold may be set at 128. Thus, a bit line feeding 128 or more than 128 memory cells in the same row would have the width adjusted from the uniform bit line width to a larger width Wb2. Meanwhile, a bit line feeding less than 128 memory cells (e.g., 64) in the same row would have the width adjusted from the uniform bit line width to a smaller width Wb1. Such adjustment may further be gated by a design house (or client) ID associated with the IC design layout 622. For example, one design house may not be endowed the option to have more than one bit line width, and thus would only use the uniform bit line width in the final design, such that operations at the layout adjustment 634 may be skipped; another design house may be endowed the option to have more than one bit line width, and the layout adjustment 634 would adjust the metal line widths for the final design. The data preparation 632 may further include other manufacturing flows such as optical proximity correction (OPC), off-axis illumination, sub-resolution assist features, other suitable techniques, or combinations thereof.

After the data preparation 632 prepares data for the mask layers, the mask fabrication 644 fabricates a group of masks including the mask that includes metal lines for bit lines. For example, an electron-beam (e-beam) or a mechanism of multiple e-beams is used to form a pattern on a mask based on data files derived from the IC design layout 622. The mask can be formed in various technologies such as binary masks, phase shifting masks, and EUV masks. For example, a binary mask includes a transparent substrate (e.g., fused quartz) and an opaque material (e.g., chromium) coated on the substrate. The opaque material is patterned according to the mask data, thereby forming opaque regions and transparent regions on the binary mask. A radiation beam, such as an ultraviolet (UV) beam, is blocked by the opaque regions and transmits through the transparent regions, thereby transferring an image of the mask to a sensitive material layer (e.g., photoresist) coated on a wafer 652. For another example, a EUV mask includes a low thermal expansion substrate, a reflective multilayer (ML) over the substrate, and an absorption layer over the ML. The absorption layer is patterned according to the mask data. A EUV beam is either absorbed by the patterned absorption layer or reflected by the ML, thereby transferring an image of the mask to a sensitive material layer (e.g., photoresist) coated on the wafer 652. In some embodiments, the fab 650 may also employ some kind of maskless lithography, such as e-beam lithography. For example, one of the masks may be based on an e-beam lithography. In such a case, the data preparation 632 may prepare the direct-write data file for the maskless lithography and the mask fabrication 644 does not make a photomask for those particular subsets to be produced by the maskless lithography.

The IC manufacturer (fab) 650, such as a semiconductor foundry, uses the masks to fabricate the IC device 660 using, for example, lithography processes. The fab 650 may include front-end-of-line (FEOL) fabrication facility and back-end-of-line (BEOL) fabrication facility. Particularly, the fab 650 implements lithography processes to define metal lines on the semiconductor wafer 652. The metal lines may include a smaller bit line width for a memory array smaller than the threshold and a larger bit line width for another memory array equals to or larger than the threshold. There may be a single threshold (e.g., a threshold of 128 for differentiating a level-1 cache and a level-2 cache) that defines two different bit line widths (e.g., Wb1 and Wb2). Alternatively, there may be two thresholds (e.g., a first threshold of 32 and a second threshold of 128 for differentiating a micro cache, a level-1 cache, and a level-2 cache) that define three different bit line widths (e.g., Wb0, Wb1, and Wb2).

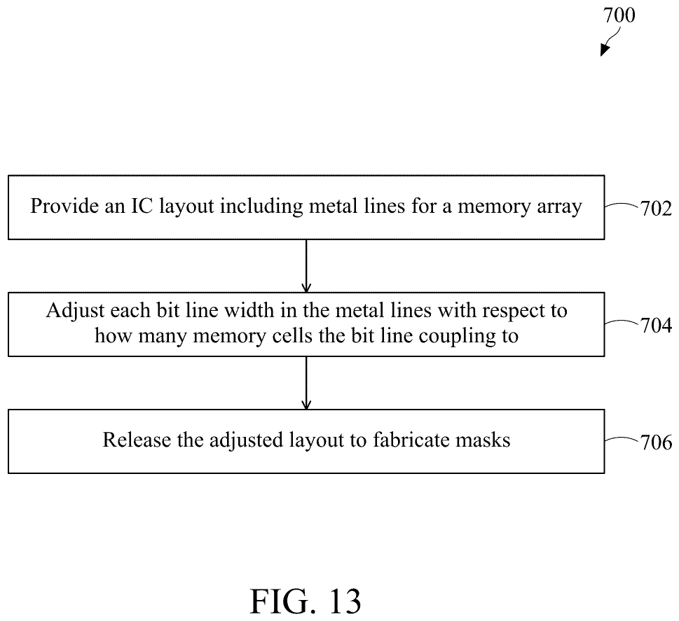

FIG. 13 illustrates a flow chart of a method 700, constructed according to various aspects of the present disclosure. Embodiments of the method 700 may be implemented by the layout adjustment 634 (FIG. 12). The method 700 is an example, and is not intended to limit the present disclosure beyond what is explicitly recited in the claims. Additional operations can be provided before, during, and after the method 700, and some operations described can be replaced, eliminated, or relocated for additional embodiments of the method. At operation 702, an IC layout including metal lines for a memory array is provided. Among the metal lines, there are metal lines representing bit lines. These bit lines have one uniform width. At operation 704, by verifying that a design house ID associated with the IC layout representing a client endowed with availability to the option of using multiple bit line widths, each bit line width is adjust with respect to how many memory cells the bit line electrically couples to. If the number of the memory cells equals to or exceeds a threshold (e.g. 128), the bit line width is adjusted from the uniform bit line width to a larger bit line width (e.g., Wb2). If the number of the memory cells is smaller than a threshold (e.g. 128), the bit line width is adjusted from the uniform bit line width to a smaller bit line width (e.g., Wb1). At operation 706, the adjusted layout is released to the mask fabrication 644 (FIG. 12) for preparing masks.

In one example aspect, the present disclosure provides a semiconductor structure. The semiconductor structure includes a first memory array in a first cache, the first memory array including a plurality of first memory cells arranged in M1 rows and N1 columns, M1 and N1 each being an integer, a first bit line coupled to a number of N1 first memory cells in one of the M1 rows, the first bit line having a first width, a second memory array in a second cache, the second memory array including a plurality of second memory cells arranged in M2 rows and N2 columns, M2 and N2 each being an integer, and a second bit line coupled to a number of N2 second memory cells in one of the M2 rows, the second bit line having a second width. N1 is smaller than N2, and the first width is smaller than the second width. In some embodiments, M1 is smaller than M2. In some embodiments, the first cache has a memory capacity smaller than the second cache, and the first cache has a speed faster than the second cache. In some embodiments, the first cache is a level-1 cache, and the second cache is a level-2 cache or a level-3 cache. In some embodiments, the first cache and the second cache are at a same cache level, and the first cache has a memory capacity smaller than the second cache. In some embodiments, N1 is less than 128, and N2 is not less than 128. In some embodiments, the first memory cells each have a first cell width and a first cell height, the second memory cells each have a second cell width and a second cell height, the first cell height is larger than the second cell height. In some embodiments, the first cell width equals the second cell width. In some embodiments, the first memory array includes a first active region for n-type transistors in the first memory cells, and a ratio of the first width and a width of the first active region ranges from about 1 to about 1.5. In some embodiments, the second memory array includes a second active region for n-type transistors in the second memory cells, and a ratio of the second width and a width of the second active region ranges from about 1.5 to about 5.

Another aspect of the present disclosure provides a memory structure. The memory structure includes a first memory array disposed in a first region of the semiconductor structure, the first memory array having a plurality of first memory cells, the first memory array including a first bit line electrically coupled to a first number of the first memory cells, and a second memory array disposed in a second region of the semiconductor structure, the second memory array having a plurality of second memory cells, the second memory array including a second bit line electrically coupled to a second number of the second memory cells. The first number is smaller than the second number, and a width of the first bit line is smaller than a width of the second bit line. In some embodiments, the first and second memory cells are static random-access memory (SRAM) cells. In some embodiments, the first region is a level-1 cache, and the second region is a level-2 cache. In some embodiments, the first number is 32 or 64, and the second number is 128, 256, or 512. In some embodiments, the first and second memory cells each have an active region for n-type transistors, a ratio of the width of the first bit line and a width of the active region ranges from about 1 to about 1.5, and a ratio of the width of the second bit line and the width of the active region ranges from about 1.5 to about 5. In some embodiments, the first memory cells each have a first active region for n-type transistors, the second memory cells each have a second active region for n-type transistors, and a width of the first active region is larger than a width of the second active region. In some embodiments, the semiconductor structure further includes a first input/output (I/O) region coupled to the first memory array, the first bit line extending continuously into the first I/O region, and a second I/O region coupled to the second memory array, the second bit line extending continuously into the second I/O region.

Yet another aspect of the present disclosure provides a method of forming a memory circuit. The method includes forming a first memory array in a first cache located in the memory circuit, the first memory array including a plurality of first memory cells, forming a second memory array in a second cache located in the memory circuit, the second memory array including a plurality of second memory cells, forming a first bit line suspended over the first memory array, the first bit line being coupled to at least a portion of the first memory cells, and forming a second bit line suspended over the second memory array, the second bit line being coupled to at least a portion of the second memory cells. A width of the first bit line is different from a width of the second bit line. In some embodiments, the first memory array is smaller than the second memory array, and the width of the first bit line is smaller than the width of the second bit line. In some embodiments, the first cache has a memory capacity smaller than the second cache, and the first cache has a speed faster than the second cache.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a first cell array located in a first cache, the first cell array including a plurality of first circuit cells arranged in a first row;
a first signal line extending through the first circuit cells in the first row as a straight line when viewed from top, the first signal line coupled to the first circuit cells;
a second cell array located in a second cache, the second cell array including a plurality of second circuit cells arranged in a second row, a size of the second cell array being greater than a size of the first cell array; and
a second signal line extending through the second circuit cells in the second row as a straight line when viewed from top, the second signal line coupled to the second circuit cells,
wherein a width of the first signal line is less than a width of the second signal line.

2. The semiconductor structure of claim 1, wherein the first and second circuit cells are static random access memory (SRAM) cells.

3. The semiconductor structure of claim 1, wherein the first and second signal lines are bit lines.

4. The semiconductor structure of claim 1, wherein the first cache has a memory capacity less than the second cache, and the first cache has a speed faster than the second cache.

5. The semiconductor structure of claim 4, wherein the first cache is a level-1 cache, and the second cache is a level-2 cache or a level-3 cache.

6. The semiconductor structure of claim 1, wherein the first cache and the second cache are at a same cache level, and the first cache has a memory capacity less than the second cache.

7. The semiconductor structure of claim 1, wherein a number of the first circuit cells is less than 128, and a number of the second circuit cells is not less than 128.

8. The semiconductor structure of claim 1, wherein the first circuit cells each have a first cell width and a first cell height, the second circuit cells each have a second cell width and a second cell height, the first cell height is greater than the second cell height, and the first cell width is equal to the second cell width.

9. The semiconductor structure of claim 1, wherein the first cell array includes a first active region for n-type transistors in the first circuit cells, and a ratio of the first width and a width of the first active region ranges from about 1 to about 1.5, and wherein the second cell array includes a second active region for n-type transistors in the second circuit cells, and a ratio of the second width and a width of the second active region ranges from about 1.5 to about 5.

10. A semiconductor structure, comprising:
a first cell array disposed in a first region of the semiconductor structure, the first cell array having a plurality of first circuit cells, the first cell array including a first signal line electrically coupled to a first number of the first circuit cells in total; and
a second cell array disposed in a second region of the semiconductor structure, the second cell array having a plurality of second circuit cells, the second cell array including a second signal line electrically coupled to a second number of the second circuit cells in total,
wherein the first number is smaller than the second number, and a width of the first signal line is less than a width of the second signal line.

11. The semiconductor structure of claim 10, wherein the first and second circuit cells are static random-access memory (SRAM) cells.

12. The semiconductor structure of claim 11, wherein the first and second signal lines are bit lines.

13. The semiconductor structure of claim 10, wherein the first region is a level-1 cache, and the second region is a level-2 cache or a level-3 cache.

14. The semiconductor structure of claim 10, wherein the first number is 32 or 64, and the second number is 128, 256, or 512.

15. The semiconductor structure of claim 10, wherein the first and second circuit cells each have an active region for n-type transistors, a ratio of the width of the first signal line and a width of the active region ranges from about 1 to about 1.5, and a ratio of the width of the second signal line and the width of the active region ranges from about 1.5 to about 5.

16. The semiconductor structure of claim 10, further comprising:
a first input/output (I/O) region coupled to the first cell array, wherein the first signal line extends continuously into the first I/O region; and
a second I/O region coupled to the second cell array, wherein the second signal line extends continuously into the second I/O region.

17. A method of forming a circuit, comprising:
forming a first cell array in a first cache located in the circuit, the first cell array including a plurality of first circuit cells arranged in a first row;
forming a second cell array in a second cache located in the circuit, the second cell array including a plurality of second circuit cells arranged in a second row;
forming a first signal line suspended over the first cell array, the first signal line electrically coupled to the first circuit cells in the first row; and
forming a second signal line suspended over the second cell array, the second signal line electrically coupled to the second circuit cells in the second row,
wherein a number of the first circuit cells is less than a number of the second circuit cells, and a width of the first signal line is less than a width of the second signal line.

18. The method of claim 17, further comprising:
based on the number of the first cell cells and the number of the circuit cells, adjusting the width of the first signal line and the width of the second signal line prior to the forming of the first and second signal lines.

19. The method of claim 17, wherein a size of the first cell array is smaller than a size of the second cell array.

20. The method of claim 19, wherein the first cache has a memory capacity smaller than the second cache, and the first cache has a speed faster than the second cache.
